(19) United States
(12) Patent Application Publication
(10) Pub. No.: US 2006/0005770 A1
(43) Pub. Date: Jan. 12, 2006

(54) Independently moving substrate supports

(76) Inventors: Robin Tiner, Santa Cruz, CA (US); Shinichi Kurita, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 10/888,947

(22) Filed: Jul. 9, 2004

(51) Int. Cl. C23C 16/00; B65G 49/07

(52) U.S. Cl. 118/728; 414/935

(57) ABSTRACT

A method and apparatus for transferring a substrate to a substrate support is provided herein. In one embodiment, a method for transferring a substrate comprises the steps of simultaneously supporting a substrate above an upper surface of a substrate support on a first set and a second set of lift pins movably disposed through the substrate support. The first set of lift pins are extended to a first height and the second set of lift pins are extended to a second height lower than the first height. The second set of lift pins are disposed inward of the first set of lift pins. The relative distance between both the first set and the second set of lift pins and the upper surface is reduced to cause the substrate to contact the upper surface smoothly and substantially continuously from a point near the center of the substrate to the edges of the substrate.

### BACKGROUND OF THE INVENTION

1. Field of the Invention

The invention relates generally to method and apparatus for placing a substrate on a substrate support in a processing chamber.

2. Description of the Related Art

Liquid crystal displays or flat panels are commonly used for active matrix displays such as computer and television monitors. Generally, flat panels comprise two plates having a layer of liquid crystal material sandwiched therebetween. At least one of the plates includes at least one conductive film disposed thereon that is coupled to a power source. Power, supplied to the conductive film from the power supply, changes the orientation of the crystal material, creating a patterned display.

In order to manufacture these displays, a substrate, such as a glass or polymer workpiece, is typically subjected to a plurality of sequential processes to create devices, conductors and insulators on the substrate. Each of these processes is generally performed in a process chamber configured to perform a single step of the production process. In order to efficiently complete the entire sequence of processing steps, a number of process chambers are typically coupled to a central transfer chamber that houses a robot to facilitate transfer of the substrate between the process chambers. A processing platform having this configuration is generally known as a cluster tool, examples of which are the families of AKT PECVD processing platforms available from AKT, a wholly-owned subsidiary of Applied Materials, Inc. of Santa Clara, Calif.

Generally, within the cluster tool, the transfer chamber robot transfers the substrates to each chamber on an end effector structure. Within each of the chambers are substrate supports upon which the robot places the substrates during transferring. Once the substrate is on the substrate support, the robot retracts from the chamber. Typically, the substrate support includes a transfer mechanism, such as a plurality of vertically moveable lift pins that are moved upwardly to engage a substrate to facilitate exchange of the substrate between the robot and the substrate support.

As demand for flat panels has increased, so has the demand for larger sized substrates. For example, large area substrates utilized for flat panel fabrication have increased in area from 550 mm by 650 mm to over 1,500 mm by 1,800 mm in just a few years and are envisioned to exceed four square meters in the near future. This growth in the size of the large area substrates has presented new challenges in handling and production. For example, to accommodate larger substrates, the lift pins in the substrate support have greater spacing between individual lift pins. This results in greater deflection, or sag, of the unsupported regions of the substrate surrounding the individual lift pins. As the lift pins are retracted to place the substrate upon the substrate support, the sagging regions come into contact with the substrate support prior to the regions beneath the lift pins, resulting in gas becoming trapped between the substrate and the substrate support in one or more locations.

The trapped gas, in turn, may cause the substrate to “float” or move on the surface of the substrate support, leading to misalignment of the substrate. Misaligned substrates may result in costly substrate damage or poor processing performance. In addition, the trapped gas pockets between the substrate and the substrate support may result in non-uniform support to substrate heat transfer, further leading to processing non-uniformities and potentially defective structures formed on the substrate.

Therefore, there is a need for an improved method and apparatus for transferring a substrate to a substrate support.

### SUMMARY OF THE INVENTION

The present invention generally provides embodiments of a method and apparatus for transferring a large area substrate onto a substrate support. The method and apparatus are utilized to transfer a large area substrate onto a substrate support in a center-to-edge manner which forces substantially all of the gas out from between the substrate and the substrate support.

In one embodiment, a support assembly for supporting a substrate in a processing chamber includes a support assembly having a support surface and a bottom surface. A first set of lift pins are movably disposed through the support assembly and have first ends for supporting the substrate disposed proximate the support surface and second ends extending beyond the bottom surface. The first ends of the first set of lift pins are extendable to a first distance above the support surface. A second set of lift pins are movably disposed through the support assembly at a position inward of the first set of lift pins. The second set of lift pins have first ends for supporting the substrate disposed proximate the support surface and second ends extending beyond the bottom surface. The first ends of the second set of lift pins are extendable independently of the first ends of the first set of lift pins to a second distance above the support surface. The second distance is less than the first distance.

In another embodiment, a support assembly for supporting a substrate in a processing chamber includes a support assembly moveable between a raised position and a lowered position and having a support surface and a bottom surface. A first set of lift pins are movably disposed through the support assembly and have first ends for supporting the substrate disposed proximate the support surface and second ends extending beyond the bottom surface. The first set of lift pins are passively actuated. The second ends of the first set of lift pins contact a bottom of the chamber at least when the support assembly is in the lowered position. A second set of lift pins are movably disposed through the support assembly and have first ends for supporting the substrate disposed proximate the support surface and second ends extending beyond the bottom surface. An actuator is disposed below the support assembly and is adapted to independently position at least one of the second set of lift pins with respect to the first set of lift pins.

In another embodiment, a method for transferring a substrate comprises the steps of simultaneously supporting a substrate above an upper surface of a substrate support on a first set and a second set of lift pins movably disposed through the substrate support. The first set of lift pins are extended to a first height and the second set of lift pins are extended to a second height lower than the first height. The second set of lift pins are disposed inward of the first set of lift pins. A relative distance between both the first set and the second set of lift pins and the upper surface is reduced to cause the substrate to contact the upper surface in a substantially continuous center-to-edge manner.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional side view of one embodiment of a processing chamber having a substrate support of the present invention;

FIGS. 2-5 are sectional side views of one embodiment of the substrate support of FIG. 1 illustrating a substrate being transferred thereto;

FIG. 6 is a sectional side view of another embodiment of a processing chamber having a substrate support;

FIG. 7 is a sectional side view of another embodiment of a processing chamber having a substrate support;

FIG. 8 is a sectional side view of another embodiment of a processing chamber having a substrate support; and

FIG. 9 is a flow chart depicting a method of transferring a substrate to a substrate support.

### DETAILED DESCRIPTION

Embodiments of the invention generally provide a substrate support and method for transferring a large area substrate that are advantageous for placing a large area substrate on a substrate support. The invention is illustratively described below in reference to a plasma enhanced chemical vapor deposition system, such as a plasma enhanced chemical vapor deposition (PECVD) system, such as is available from AKT, a division of Applied Materials, Inc., Santa Clara, Calif. However, it should be understood that the invention has utility in other system configurations such as physical vapor deposition systems, ion implant systems, etch systems, chemical vapor deposition systems and other systems in which transferring a substrate to a substrate support is desired.

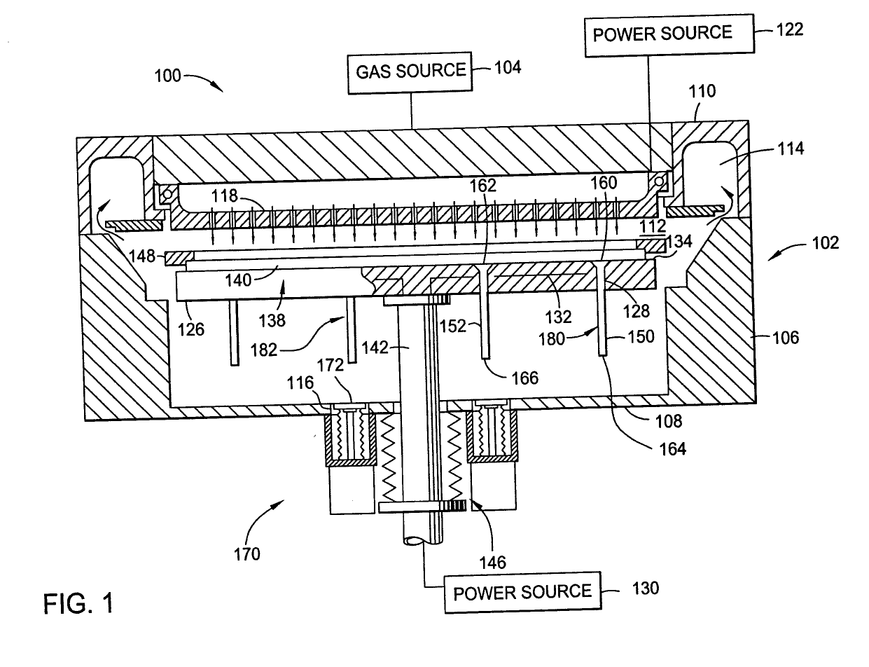

FIG. 1 is a sectional side view of one embodiment of a plasma enhanced chemical vapor deposition (PECVD) system 100. The system 100 generally includes a chamber 102 coupled to a gas source 104. The chamber 102 has walls 106, a bottom 108 and a lid assembly 110 that define a process volume 112. The process volume 112 is typically accessed through a port (not shown) in the walls 106 that facilitates movement of the substrate 140 into and out of the chamber 102. The walls 106 and bottom 108 are typically fabricated from a unitary block of aluminum. The lid assembly 110 contains a pumping plenum 114 that couples the process volume 112 to an exhaust port (that includes various pumping components, not shown).

The lid assembly 110 is supported by the walls 106 and can be removed to service the chamber 102. The lid assembly 110 is generally comprised of aluminum and may additionally contain heat transfer fluid channels for regulating the temperature of the lid assembly 110 by flowing heat transfer fluid therethrough.

A distribution plate 118 is coupled to an interior side 120 of the lid assembly 110. The distribution plate 118 is typically fabricated from aluminum. The distribution plate generally includes a perimeter mounting ring that surrounds a “dish-shaped” center section. The mounting ring includes a plurality of mounting holes passing therethrough, each accepting a vented mounting screw that threads into a mating hole in the lid assembly 110. The center section includes a perforated area through which process and other gases supplied from the gas source 104 are delivered to the process volume 112. The perforated area of the distribution plate 118 is configured to provide uniform distribution of gases passing through the distribution plate 118 into the chamber 102.

A heated support assembly 138 is centrally disposed within the chamber 102. The support assembly 138 supports a substrate 140 during processing. In one embodiment the substrate 140 comprises a large area (e.g., greater than 0.25 square meters) glass or polymer workpiece. The support assembly 138 is generally fabricated from aluminum, ceramic, or a combination of aluminum and ceramic. The support assembly 138 typically includes at least one embedded heating element 132. A vacuum port (not shown) is used to apply a vacuum between the substrate 140 and support assembly 138, securing the substrate to the substrate support assembly 138 during processing. The heating element 132, such as an electrode or resistive element disposed in the support assembly 138, is coupled to a power source 130, heating the support assembly 138 and substrate 140 positioned thereon to a predetermined temperature. In one embodiment, the heating element 132 maintains the substrate 140 at a uniform temperature of about 150 to 400 degrees. Alternatively, heating lamps or other heat sources may be utilized to heat the substrate.

Generally, the support assembly 138 is coupled to a stem 142. The stem 142 provides a conduit for electrical leads, vacuum and gas supply lines between the support assembly 138 and other components of the system 100. The stem 142 couples the support assembly 138 to a lift system (not shown) that moves the support assembly 138 between an elevated position (as shown) and a lowered position. Bellows 146 provides a vacuum seal between the chamber volume 112 and the atmosphere outside the chamber 102 while facilitating the movement of the support assembly 138.

The support assembly 138 generally is grounded such that RF power supplied by a power source 122 to the distribution plate 118 (or other electrode positioned within or near the lid assembly of the chamber) may excite the gases disposed in the process volume 112 between the support assembly 138 and the distribution plate 118. The RF power, generally having a frequency of between a few Hz to 13 MHz or higher is provided in a wattage suitable for the substrate surface area. In one embodiment, the power source 122 comprises a dual frequency source that provides a low frequency power at less than about 2 MHz (preferably about 200 to 500 kHz) and a high frequency power at greater than 13 MHz (preferably about 13.56 kHz). The frequencies may be fixed or variable. Illustratively, for a 550 mm×650 mm substrate, the low frequency power is about 0.3 to about 2 kW while the high frequency power is about 1 to 5 kW. Generally, the power requirements decrease or increase with a corresponding decrease or increase in substrate size.

The support assembly 138 additionally supports a circumscribing shadow frame 148. The shadow frame 148 is configured to cover the edge of the substrate 140 and is typically comprised of ceramic. Generally, the shadow frame 148 prevents deposition at the edge of the substrate 140 and support assembly 138 so that the substrate does not stick to the support assembly 138. Optionally, a purge gas is supplied between the shadow frame 148 and the support assembly 138 to assist in preventing deposition at the substrate's edge.

The support assembly 138 has a plurality of holes 128 disposed therethrough to accept a plurality of lift pins 150 comprising a first set 180 and one or more other lift pins 152 that comprises a second set 182. The second set 182 of lift pins 152 are positioned inward of the first set 180 of lift pins 150. The lift pins 150 and 152 are typically comprised of ceramic or anodized aluminum. Generally, the lift pins 150 and 152 have respective first ends 160 and 162 that are substantially flush with, or slightly recessed from, a support surface 134 of the support assembly 138 when the lift pins 150 and 152 are in a normal position (i.e., retracted relative to the support assembly 138). The first ends 160, 162 are generally flared to prevent the lift pins 150, 152 from falling through the holes 128. Additionally, the lift pins 150 and 152 have respective second ends 164 and 166 that extend beyond an underside 126 of the support assembly 138.

The lift pins 150, 152 move to a position when actuated where the pins project from the support surface 134. In the actuated position, the lift pins 150 may project farther from the support surface 134 than the lift pins 152. Alternatively, the lift pins 150 and the lift pins 152 may project the same distance from the support surface 134. In one embodiment, the first set 180 of lift pins 150 includes at least eight lift pins that are positioned outwards of the one or more lift pins 152. In one embodiment, the first set 180 of lift pins 150 include eight pins grouped in pairs wherein a respective pair is positioned proximate each side of a four-sided substrate. In one embodiment, the second set 182 of lift pins 152 includes four lift pins positioned about a center of the support assembly 138. It is contemplated that any number of lift pins may be utilized in any geometric or random pattern. For example, the substrate 140 may be a mother substrate having many features being formed thereon and intended for subsequent separation into smaller units. The second set 182 of lift pins 152 may be arranged to be situated between the features to prevent inadvertent damage during substrate handling.

The lift pins 150, 152 may be displaced relative to the support surface 134 of the support assembly 138 to facilitate transfer of the substrate 140 to the support assembly 138. One or more actuators 170 are disposed below the support assembly 138 and are adapted to control the displacement of at least one of the first or second sets 180, 182 of lift pins 150, 152 relative to the support surface 134 of the support assembly 138. The one or more actuators 170 may be a pneumatic cylinder, hydraulic cylinder, lead screw, solenoid, stepper motor, or other device suitable for controlling the displacement of the lift pins 150, 152. Controlling the displacement of at least one of the first and second sets 180, 182 of lift pins 150, 152 allows for control of the profile of the substrate 140 supported by the lift pins 150, 152 as it is brought into contact with the support surface 134 of the support assembly 138. By controlling the profile of the substrate 140, the substrate 140 may be brought into contact with the support surface 134 in a substantially continuous center-to-edge manner, thereby enabling transfer of the substrate 140 without substantially trapping air between the substrate 140 and the support surface 134. Continuous, as used herein, refers to physical continuity, and not temporal continuity. The substrate 140 may be raised, lowered, or held stationary at various moments during the transfer to or from the support assembly 138.

In one embodiment, the actuators 170 are adapted to displace only the second set 182 of lift pins 152 and the first set 180 of lift pins 150 are passively actuated. Passive actuation, as used herein, means that the first set 180 of lift pins 150 are moved relative to the support assembly 138 by contact with a stationary object, such as the bottom 108 of the chamber 102, when the support assembly 138 is lowered. Alternatively, the actuators 170 may displace both the first and the second sets 180, 182 of lift pins 150, 152.

In one embodiment, the actuators 170 may be coupled to the bottom 108 of the chamber 102 in general alignment with the second set 182 of lift pins 152. A plurality of holes 116 formed in the bottom 108 of the chamber 102 allow each actuator 170 to move a strike plate 172 up and down relative to the bottom 108 of the chamber 102. The strike plate 172 is typically comprised of ceramic or anodized aluminum. The stroke of the actuators 170 controls the amount of displacement of the lift pins 152 and will generally depend on the configuration of the support assembly 138. For example, in one embodiment, the lift pins 150, 152 are of equal length and are actuated as the support assembly 138 lowers and the second ends 164, 166 of the lift pins 150, 152 contact the chamber bottom 108 and the strike plate 172, respectively. The actuators 170 may have a stroke that enables the strike plate 172 to be positioned in a range of from at least substantially co-planar with the chamber bottom 108 to a position lower than the chamber bottom 108 sufficient to control the shape of the substrate 140, as discussed more fully below.

Alternatively, in another embodiment where the lift pins 150 are longer than the lift pins 152, the actuator 170 may have a longer stroke, or be positioned higher, in order to actuate the lift pins 152 as desired. It is contemplated that any combination of relative lengths of the sets 180, 182 of lift pins 150, 152 may be compensated for by the position and/or stroke length of the actuators 170. Furthermore, it is contemplated that the actuators 170 may be coupled directly to the lift pins 152 rather than utilizing the strike plate 172. Optionally, one or more actuators, not shown, may additionally be disposed below the support assembly 138 and adapted to actuate the first set of lift pins 180.

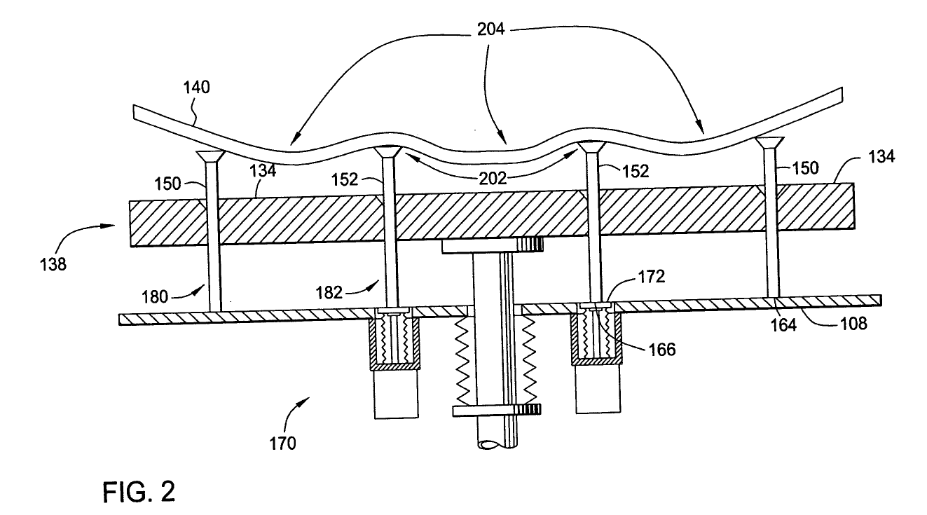

FIGS. 2-5 depict partial sectional side views of the substrate support of the present invention illustrating one mode of operation which advantageously overcomes the deficiencies in the prior art. Specifically, FIG. 2 is a partial sectional view of a substrate support 138 supporting a substrate 140 thereon in a raised position suitable, for example, for transferring the substrate 140 into or out of the processing chamber 102. Due to the size of the substrate 140, areas 204 which are not supported by the lift pins 150, 152 will sag. The high temperature of the processing chamber 102 may exacerbate this effect causing even greater sag. Although the first and the second sets 180, 182 of lift pins 150, 152 are shown extended to a substantially equivalent height above the support assembly 138, it is contemplated that the second set 182 of lift pins 152 may be at a different height than the first set 180 of lift pins 150 when the substrate 140 is first placed upon the lift pins 150, 152.

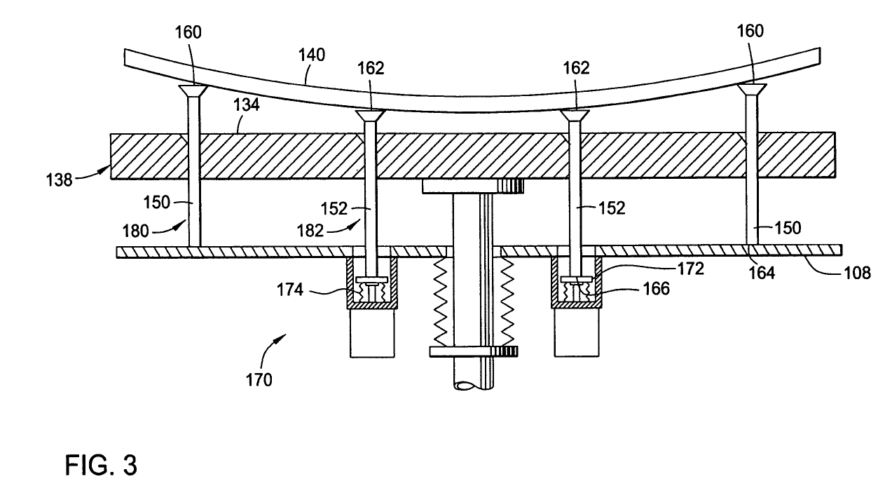

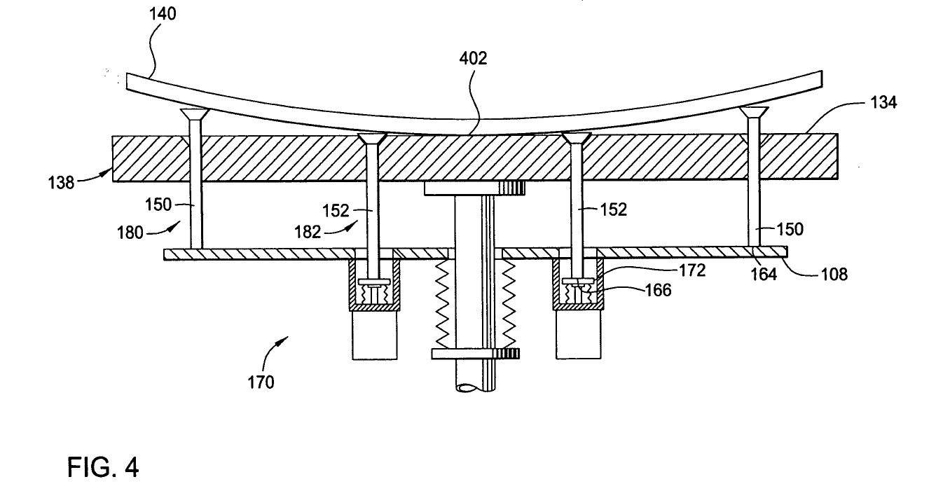

As shown in FIG. 3, the profile of the substrate 140 may be controlled to form a more arcuate shape. In one embodiment, this may be accomplished by lowering the inner, second set 182 of lift pins 152 by the actuators 170. The inner, second set 182 of lift pins 152 move independently of the outer, first set 180 of lift pins 150. As shown in FIG. 4, a center portion 402 of the substrate 140 is brought into contact with the support surface 134 of the support assembly 138. This may be accomplished by raising the support assembly 138 to come into contact with the substrate 140. Alternatively, the first and second sets 180, 182 of lift pins 150, 152 may be lowered or some other combination of movements of the support assembly 138 and the first and second sets 180, 182 of lift pins 150, 152 to bring the center portion 402 of the substrate 140 into contact with the support surface 134.

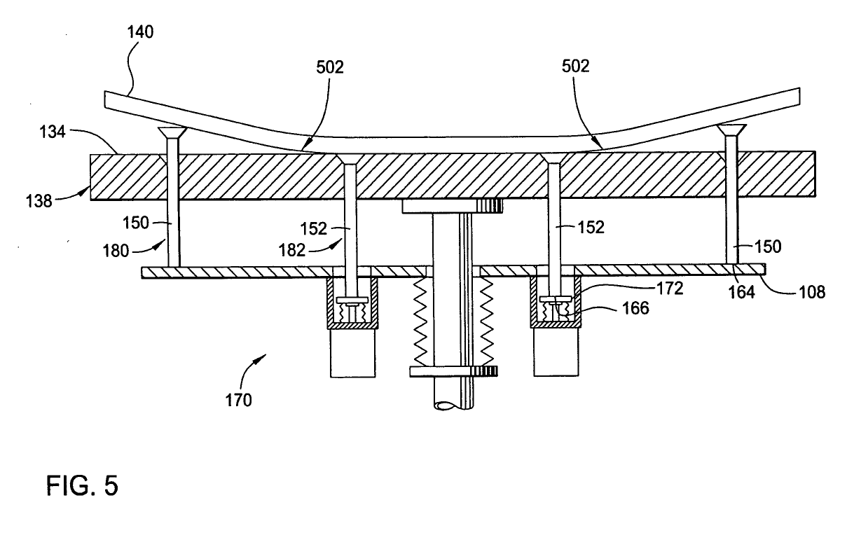

As shown in FIG. 5, as the relative distance between the support assembly 138 and the substrate 140 continues to lessen, the substrate 140 smoothly comes into contact with the support assembly 138 along a rolling contact point 502. The rolling contact point 502 progressively moves outward to squeeze out the air from between the substrate 140 and the support surface 134 of the support assembly 138. Thus, when the transfer of the substrate 140 to the support assembly 138 is completed, the substrate 140 is uniformly positioned on the support assembly 138 with substantially no gas entrained between the substrate 140 and the support surface 134 of the support assembly 138.

Although the description and drawings depict a method of transferring the substrate 140 in a center to edge manner, it is also contemplated that the substrate 140 could be transferred from one side to the other, e.g., left-to-right, right-to-left, and the like. Specifically, one skilled in the art looking at the placement sequence depicted in FIGS. 2-5, could readily arrange and control the actuators 170 and lift pins 150, 152 to place the substrate 140 onto the support assembly 138 in a side-to-side manner that squeezes out the air from between the substrate 140 and the support surface 134 of the support assembly 138 as discussed above.

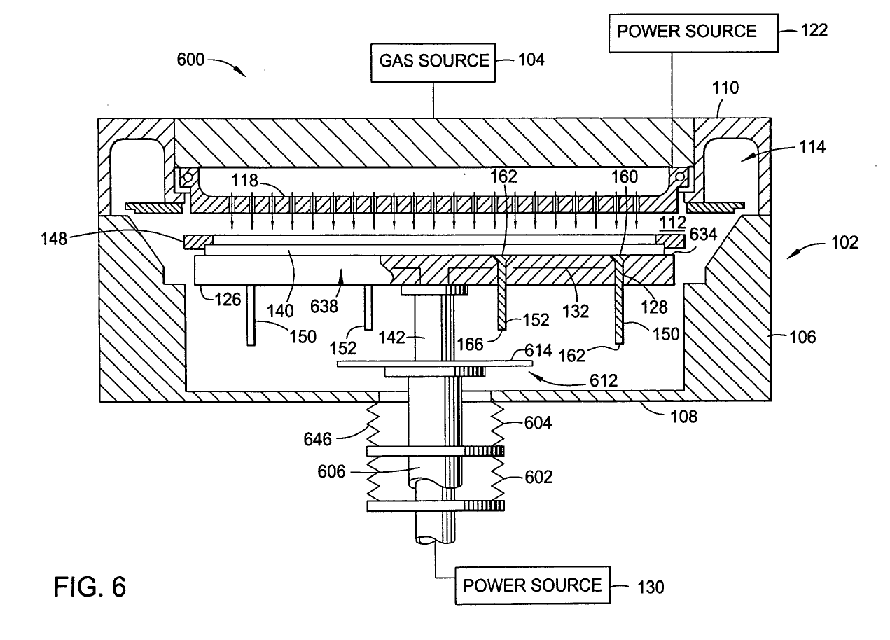

FIG. 6 depicts another embodiment of a PECVD system 600 having a support assembly 638 suitable for processing large area substrates. The system 600 is substantially similar to the system 100 described with respect to FIG. 1, with the exception of the details described below.

A lift plate 612 is disposed proximate the underside 126 of the support assembly 638. The lift plate 612 is disposed below the second ends 166 of the second set 182 of lift pins 152 such that the lift plate 612 may contact the lift pins 152 and cause them to extend from the support surface 634 of the support assembly 638. The lift plate 612 is coupled to an actuator such as a pneumatic cylinder, hydraulic cylinder, lead screw, solenoid, stepper motor, or other motion device (not shown) that is typically positioned outside of the process volume 112. The lift plate 612 is connected to the actuator by a collar 606 that circumscribes a portion of the stem 142. A bellows 646, similar to bellows 146 in FIG. 1, includes an upper portion 604 and a lower portion 602 that allow the stem 142 and collar 606 to move independently while maintaining the isolation of the process volume 112 from the environment exterior to the chamber 102. Alternatively, the motions of the lift plate 612 and support assembly 638 may be controlled via a single actuator utilizing a spring and a motion stop that controls the relative motion between the lift plate 612 and support assembly 638.

Generally, the lift plate 612 is actuated to control the position of the lift pins 152 relative to the support surface 634 of the support assembly 638 and the lift pins 150. By controlling the amount of extension of the lift pins 152 above the support surface 634 relative to the amount of extension of the lift pins 150 from the support surface 634, the shape of the substrate 140 may be controlled to ensure proper placement of the substrate 140 on the support assembly 638 in a progressive center-to-edge manner, as discussed above. The support assembly 638 may move relative to lift plate 612 either by moving the support assembly 638, moving the lift plate 612, or a combination thereof.

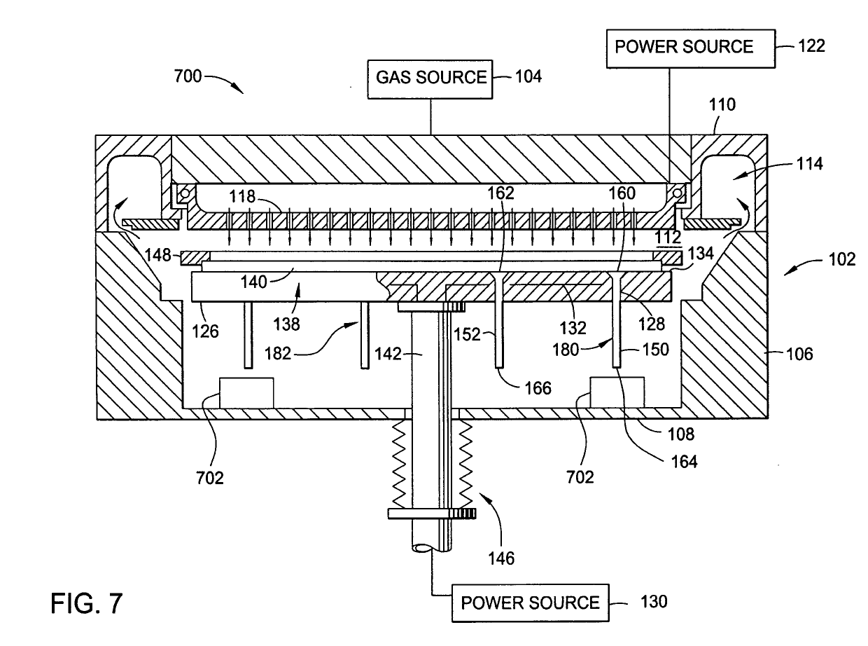

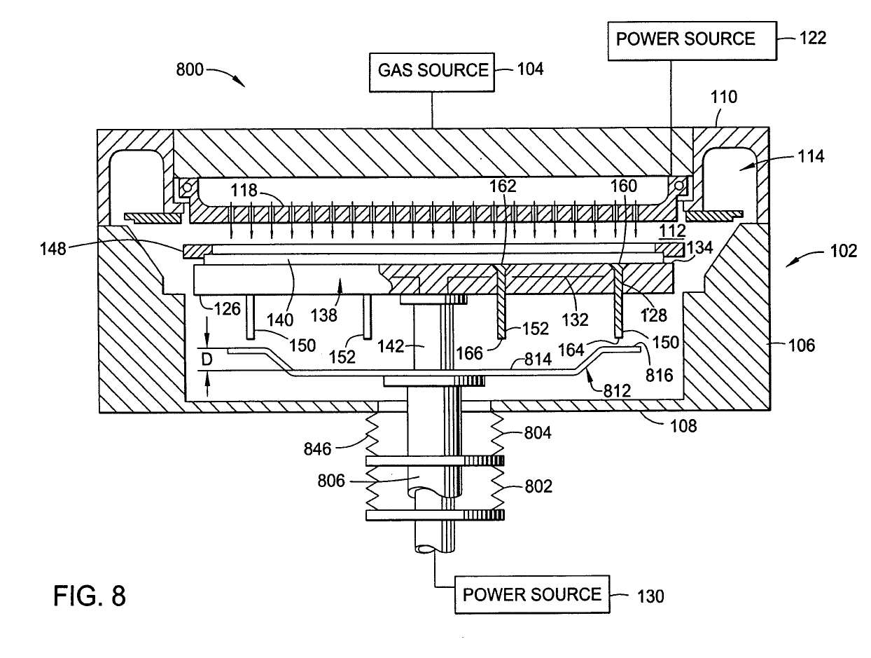

In the embodiments depicted in FIGS. 7 and 8, the desired relative position of the first set 180 of lift pins 150 and the second set 182 of lift pins 152 is predetermined based upon the calculated deflection, or sag, of the substrate 140. The calculated deflection is generally based upon the physical characteristics of the substrate 140 and processing conditions within the processing chamber 102, for example, temperature.

In the embodiment depicted in FIG. 7, a PECVD system 700 is shown having a support assembly 738 disposed in a chamber 102. A plurality of offsets 702 are disposed on the bottom 108 of the chamber 102 beneath each of the first set 180 of lift pins 150. Each of the offsets 702 has a height D. As the support assembly 738 is lowered, the second ends 164 of the lift pins 150 contact the offset 702 while the second ends 166 of the lift pins 152 contact the bottom 108 of the chamber 102. The contact of the lift pins 150, 152 respectively with the offset 702 and bottom 108 causes the lift pins 150, 152 to stop moving as the support assembly 738 continues to descend, thereby causing the first ends 160, 162 of the lift pins 150, 152 to extend above the support surface 734 of the support assembly 738.

Due to the presence of the offset 702 on the chamber bottom 108, the first set 180 of lift pins 150 will be higher than the second set 182 of lift pins 152 by the height D of the offset 702. The height D is calculated to maintain a desired profile of a substrate 140 placed upon the extended lift pins 150, 152 such that, upon raising the support assembly 738, the substrate 140 comes into contact with the support surface 734 of the support assembly 738 smoothly and continuously from the center of the substrate 140 towards the outer edges of the substrate 140. As discussed above, this advantageously forces the gas out from between the substrate 140 and the support surface 734 of the support assembly 738. Alternatively, the lift pins 150 may be longer than the lift pins 152 by the calculated height D without the need for the offset 702 to be disposed in the bottom 108 of the chamber 102.

In the embodiment depicted in FIG. 8, a PECVD system 800 is shown having a support assembly 838 disposed in a processing chamber 102. The system 800 is substantially similar to the system 600 described with respect to FIG. 6, with the exception of the following details.

A lift plate 812 is disposed proximate the underside 126 of the support assembly 838. The lift plate 812 is coupled to an actuator (not shown) as described with reference to FIG. 6, above. The lift plate 812 may move relative to the support assembly 838 either by moving the support assembly 838, moving the lift plate 812, or a combination thereof.

The lift plate 812 is disposed below the second ends 164, 166 of the lift pins 150, 152 such that the lift plate 812 may contact the lift pins 150, 152 and cause them to extend from the support surface 834 of the support assembly 838. The lift plate 812 has an inner surface 814 and a raised outer surface 816. The outer surface 816 is disposed at a height D above the inner surface 814.

Generally, the lift plate 812 is actuated to control the position of the lift pins 150, 152 relative to the support surface 834 of the support assembly 838. The difference in height D between the inner and outer surfaces 814, 816 of the lift plate 812 is calculated to maintain a desired profile of a substrate 140 placed upon the extended lift pins 150, 152 such that, upon lowering the lift pins 150, 152, the substrate 140 comes into contact with the support surface 834 of the support assembly 838 smoothly, continuously, and progressively from the center of the substrate 140 towards the outer edges of the substrate 140. As discussed above, this advantageously forces the air out from between the substrate 140 and the support surface 834 of the support assembly 838. Alternatively, the lift pins 150 may be longer than the lift pins 152 by the calculated height D without the need for the difference in height between the inner surface 814 and the outer surface 816 of the lift plate 812.

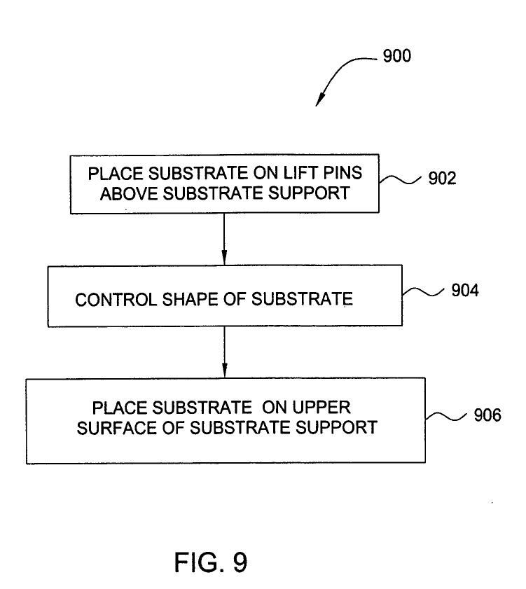

FIG. 9 depicts a flow chart of a method 900 for placing a substrate upon a substrate support. The method 900 begins at step 902 where a substrate 140 is placed, typically by a robot, on the lift pins 150, 152 above the support assembly 138 as shown in FIG. 2. Alternatively, the second set of lift pins 182 may already be lower than the first set of lift pins 180, as shown in FIG. 3. At optional step 904, the shape of the substrate is manipulated to the predefined profile by adjusting the relative extensions of the inner and outer lift pins 150, 152. In one embodiment, the inner lift pins 152 are lowered relative to the support surface 134 to control the profile of the substrate 140 to be substantially arcuate, as shown in FIG. 3.

At step 906, the support assembly 138 is raised to place the substrate 140 in position on the support surface 134 of the support assembly 138. As seen in FIGS. 4 and 5, a center portion 402 of the substrate 140 comes into contact with the support surface 134 of the support assembly 138 prior to any other portion of the substrate 140. As shown in FIG. 5, as the substrate support continues to rise, the substrate 140 comes into contact with the support surface 134 of the support assembly 138 along rolling contact points 502 which act to squeeze out any gas from between the substrate 140 and the support surface 134 of the support assembly 138 until the substrate 140 rests completely flat on the support surface 134 of the support assembly 138, as shown in FIG. 1. Alternatively, the support assembly 138 may be stationary and the first and the second set of lift pins 180, 182 may be actuated to lower the substrate 140 onto the support surface 134, or the support assembly 138 and the first and the second set of lift pins 180, 182 may both move.

While the foregoing is directed to embodiments of the present invention, other and further embodiments of the invention may be devised without departing from the basic scope thereof, and the scope thereof is determined by the claims that follow.

What is claimed is:

1. A support assembly for supporting a substrate in a processing chamber comprising:
a support assembly having a support surface and a bottom surface;
a first set of lift pins movably disposed through the support assembly and having a first end for supporting the substrate disposed proximate the support surface and a second end extending beyond the bottom surface, wherein the first end of the first set of lift pins is extendable to a first distance above the support surface; and
a second set of lift pins movably disposed through the support assembly at a position inward of the first set of lift pins and having a first end for supporting the substrate disposed proximate the support surface and a second end extending beyond the bottom surface, wherein the first end of the second set of lift pins is extendable independently of the first set of lift pins to a second distance above the support surface, the second distance less than the first distance.

2. The support assembly of claim 1, wherein the second set of lift pins comprises at least four lift pins.

3. The support assembly of claim 1, wherein the second set of lift pins comprises four lift pins spaced at approximately 90 degree intervals around a center of the support assembly.

4. The support assembly of claim 1, wherein the first set of lift pins comprises at least eight lift pins.

5. The support assembly of claim 1, wherein the first set of lift pins comprises four pairs of lift pins adapted to be positioned proximate each side of a four-sided substrate.

6. The support assembly of claim 1, wherein the first set of lift pins have a first length that is longer than a second length of the second set of lift pins.

7. The support assembly of claim 1, further comprising:
an actuator disposed below the support assembly; and
a lift plate coupled to the actuator and positioned to displace the second set of lift pins when elevated by the actuator.

8. The support assembly of claim 1, further comprising:
at least one actuator disposed below the support assembly and engaging at least one of the second set of lift pins without engaging the first set of lift pins.

9. The support assembly of claim 1, further comprising:
a plurality of actuators disposed below the support assembly and respectively engaging a respective lift pin of the second set of lift pins.

10. A support assembly for supporting a substrate in a processing chamber comprising:
a support assembly having a support surface and a bottom surface, the support assembly moveable between a raised position and a lowered position;
a first set of lift pins movably disposed through the support assembly and having a first end for supporting the substrate disposed proximate the support surface and a second end extending beyond the bottom surface, wherein the second end of the first set of lift pins contacts a bottom of the chamber when the support assembly is in the lowered position;
a second set of lift pins movably disposed through the support assembly and having a first end for supporting the substrate disposed proximate the support surface and a second end extending beyond the bottom surface; and
an actuator disposed below the support assembly adapted to independently position at least one of the second set of lift pins with respect to the first set of lift pins.

11. The support assembly of claim 10, wherein the second set of lift pins are positioned inward of the first set of lift pins.

12. The support assembly of claim 10, wherein the second set of lift pins comprises four lift pins.

13. The support assembly of claim 10, wherein the second set of lift pins comprises four lift pins positioned substantially equidistantly around a center of the support assembly.

14. The support assembly of claim 10, wherein the first set of lift pins comprises at least eight lift pins.

15. The support assembly of claim 10, wherein the first set of lift pins comprises four pairs of lift pins adapted to be positioned proximate each side of a four-sided substrate.

16. The support assembly of claim 10, wherein the actuator further comprises:
a set of actuators, each actuator being disposed in a hole formed in the bottom of the chamber.

17. The support assembly of claim 10, further comprising:
a lift plate positioned below the support assembly and coupled to the actuator, the lift plate adapted to contact the second end of the second set of lift pins.

18. A method for transferring a substrate to a substrate support, the substrate having a central region and an outer region, comprising:
simultaneously supporting a substrate above an upper surface of a substrate support on a first set and a second set of lift pins movably disposed through the substrate support; and
reducing a relative distance between both the first set and the second set of lift pins and the upper surface to cause the substrate to contact the upper surface progressively and substantially continuously from a central region of the substrate to an outer region of the substrate.

19. The method of claim 18, wherein the first set of lift pins are initially extended to a first height and the second set of lift pins extended to a second height lower than the first height, and wherein the second set of lift pins are disposed inward of the first set of lift pins

20. The method of claim 18, wherein the step of reducing the relative distance further comprises raising the substrate support.

21. The method of claim 20, wherein the substrate support is disposed in a processing chamber having a bottom with a raised portion of the bottom adapted to contact a bottom portion of the first set of lift pins.

22. The method of claim 18, wherein the step of reducing the relative distance further comprises lowering a lift plate disposed below the substrate support and supporting a bottom of the second set of lift pins.

23. The method of claim 22, wherein the lift plate further supports a bottom of the first set of lift pins.

24. A method for transferring a substrate to a substrate support comprising:
simultaneously supporting a substrate above an upper surface of a substrate support on a first set and a second set of lift pins movably disposed through the substrate support, the first and the second set of lift pins respectively extending a first and a second distance above the upper surface, the second set of lift pins being disposed inward of the first set of lift pins;
contacting the upper surface of the substrate support with a central portion of the substrate by retracting the second set of lift pins relative to the substrate support; and
contacting the upper surface of the substrate support with an outer portion of the substrate in a continuous center-to-edge manner after the center of the substrate is in contact with the upper surface by retracting the first set of lift pins relative to the substrate support.

25. The method of claim 24, wherein the first distance and the second distance are substantially equal when the substrate is first placed upon the first and the second sets of lift pins.

26. The method of claim 24, wherein the steps of retracting the first and the second sets of lift pins relative to the substrate support further comprises raising the substrate support.

27. The method of claim 24, wherein the substrate support is disposed in a processing chamber having a bottom with a raised portion of the bottom adapted to contact a bottom portion of each of the lift pins contained in the first set of lift pins.

28. The method of claim 24, wherein the step of retracting the second set of lift pins relative to the substrate support further comprises lowering a lift plate disposed below the substrate support and supporting a bottom of the second set of lift pins.

29. The method of claim 28, wherein the lift plate further supports a bottom of the first set of lift pins and wherein the step of retracting the first set of lift pins relative to the substrate support further comprises lowering the lift plate.

30. The method of claim 24, wherein the step of lowering the center of the substrate further comprises:
retracting the first set of lift pins relative to the substrate support at a first rate less than a second rate at which the second set of lift pins is retracted.

31. The method of claim 30, wherein the step of contacting the upper surface of the substrate support further comprises:
retracting the first set of lift pins relative to the substrate support at a first rate less than a second rate at which the second set of lift pins is retracted.

32. The method of claim 24, wherein the step of contacting the upper surface of the substrate support further comprises:
retracting the first set of lift pins relative to the substrate support at a first rate less than a second rate at which the second set of lift pins is retracted.

33. The method of claim 24, contacting the upper surface of the substrate support further comprises:
displacing gas from between the substrate and substrate support from a center to edge progression.

34. A method for transferring a substrate to a substrate support comprising:
supporting a substrate having a sagging central portion above an upper surface of a substrate support on a first and a second set of lift pins movably disposed through the substrate support, the first and the second set of lift pins respectively extending a first and a second distance above the upper surface, the second set of lift pins being disposed inward of the first set of lift pins;
retracting at least the second set of lift pins relative to the substrate support to cause the sagging central portion of the substrate to contact the upper surface prior to an outer portion of the substrate; and
retracting at least the first set of lift pins relative to the substrate support to cause the substrate to contact the upper surface in a substantially continuous center-to-edge manner.

35. A method for transferring a substrate to a substrate support comprising:
supporting a substrate above a substrate support wherein the substrate has at least two regions sagging below surrounding regions of the substrate;
transferring the substrate to the substrate support in a manner that expels gas from between the substrate support in a center to edge progression.

36. The method of claim 35, wherein the step of transferring further comprises:
contacting the substrate to the substrate support in a substantially continuous center-to-edge manner.

37. The method of claim 35, wherein the step of transferring prevents gas from becoming trapped in pockets between the substrate and substrate support.
